(19) United States
(12) Patent Application Publication
(10) Pub. No.: US 2026/0063860 A1
(43) Pub. Date: Mar. 5, 2026

(54) OPTICAL MODULE ASSEMBLY AND FIBER OPTIC CONNECTOR WITH IMPROVED ARRANGEMENT OF OPTICAL FIBER

(71) Applicants: DONGGUAN XUNTAO ELECTRONIC CO., LTD., Dongguan City (CN); DONGGUAN LUXSHARE TECHNOLOGIES CO., LTD, Dongguan City (CN)

(72) Inventors: CHUNG-HSIN FU, Dongguan City (CN); Chih-Wei YU, Dongguan City (CN); Chien-Wen LU, Dongguan City (CN); Min-Sheng KAO, Dongguan City (CN); Yi-Tseng LIN, Dongguan City (CN)

(73) Assignees: DONGGUAN XUNTAO ELECTRONIC CO., LTD., Dongguan City (CN); DONGGUAN LUXSHARE TECHNOLOGIES CO., LTD, Dongguan City (CN)

(21) Appl. No.: 18/917,198

(22) Filed: Oct. 16, 2024

(30) Foreign Application Priority Data
Aug. 28, 2024 (CN) 202411198280.1

(51) Int. Cl. G02B 6/42; G02B 6/43; H01L 25/16

(52) U.S. Cl. CPC G02B 6/428; G02B 6/4269; G02B 6/4278; G02B 6/43

(57) ABSTRACT

An optical module assembly includes a printed circuit board, a substrate mounted on the printed circuit board, an emitting chip mounted on the substrate, a silicon photonic chip mounted on the substrate, an optical fiber connected to the silicon photonic chip to transmit an optical signal, a daughter board mounted on the printed circuit board, and an electrical chip mounted on the daughter board. The optical fiber and the printed circuit board are spaced at a certain distance so as not to interfere with each other. An optical fiber connector including the optical module assembly is also disclosed.

### CROSS-REFERENCE TO RELATED APPLICATION

This patent application claims priority of a Chinese Patent Application No. 202411198280.1, filed on Aug. 28, 2024 and titled “OPTICAL MODULE ASSEMBLY AND FIBER OPTIC CONNECTOR”, the entire content of which is incorporated herein by reference.

### TECHNICAL FIELD

The present disclosure relates to an optical module assembly and an optical fiber connector, which belongs to the technical field of optical module structures.

### BACKGROUND

An optical fiber connector in the related art includes a shell and an optical module assembly at least partially located in the shell. The optical module assembly includes a printed circuit board, an emitting chip and a silicon photonic chip, etc.

The optical module assembly in the related art is usually suitable for multi-channel single wavelength. The emitting chip is used to transmit optical signals. The optical signals are transmitted into a light-receiving chip and finally converted into electrical signals through an electrical chip. The light-receiving chip may be a silicon photonic chip. The silicon photonic chip includes a splitter and a plurality of optical modulators. The splitter splits the optical signals into corresponding paths. Optical signals and electrical signals are input into the optical modulator together and converted into output signals.

Referring to FIG. 1 and FIG. 2, from a structural point of view, the optical module assembly in the related art usually includes a metal base 1′, a PCB (printed circuit board) board 2′ mounted on the metal base 1′ and an electrical chip 3′ mounted on the PCB board 2′. The PCB board 2′ defines a hollow portion 21′ to accommodate an emitting chip 4′, a silicon photonic chip 5′ and an optical module 6′. The optical module 6′ includes an optical isolator 61′ and two lenses 62′ respectively located on two sides of the optical isolator 61′, respectively.

It is understandable to those skilled in the art that in order to minimize signal loss, it is preferable that the emitting chip 4′ and the silicon photonic chip 5′ are located at a same height. However, mounting the emitting chip 4′ and the silicon photonic chip 5′ in the hollow portion 21′ provided on the PCB board 2′ will cause the usable area of the PCB board 2′ to be reduced. This is not conducive to improving and expanding the functions of the PCB board 2′, nor does it adapt to the development trend of increasingly complex optical module assemblies.

As shown in FIG. 1, the emitting chip 4′ is used to emit optical signals. The optical signals pass through the optical module 6′ and are input into the silicon optical chip 5′ through a waveguide 7′. As shown in FIG. 2, the silicon optical chip 5′ is connected to an optical fiber 9′ through a fiber array (FA) 8′. At this time, the arrangement of the optical fiber 9′ will be a problem because the optical fiber 9′ easily interferes with a surface of the PCB board 2′.

It should be noted that the related art in FIG. 1 and FIG. 2 is not the prior art of the present disclosure, unless there is other evidence to the contrary.

Therefore, it is desirable to improve the optical module assembly and the optical fiber connector in related art.

### SUMMARY

An object of the present disclosure is to provide an optical module assembly and an optical fiber connector in which an optical fiber can be easily arranged.

In order to achieve the above object, the present disclosure adopts the following technical solution: an optical module assembly, including: a printed circuit board; a substrate, the substrate being mounted on the printed circuit board; an emitting chip, the emitting chip being mounted on the substrate; a silicon photonic chip, the silicon photonic chip being mounted on the substrate; an optical fiber, the optical fiber being connected to the silicon optical chip to transmit optical signals; a daughter board, the daughter board being mounted on the printed circuit board; and an electrical chip, the electrical chip being mounted on the daughter board; wherein the optical fiber and the printed circuit board are separated by a distance so as not to interfere with each other.

In order to achieve the above object, the present disclosure adopts the following technical solution: an optical fiber connector, including: a first metal shell, the first metal shell including a first extension portion; a second metal shell, the second metal shell including a second extension portion; and an optical module assembly, the optical module assembly, including: a printed circuit board, the printed circuit board including a tongue plate; a substrate, the substrate being mounted on the printed circuit board; an emitting chip, the emitting chip being mounted on the substrate; a silicon photonic chip, the silicon photonic chip being mounted on the substrate; an optical fiber, the optical fiber being connected to the silicon optical chip to transmit optical signals; a daughter board, the daughter board being mounted on the printed circuit board; and an electrical chip, the electrical chip being mounted on the daughter board; wherein the optical fiber and the printed circuit board are separated by a distance so as not to interfere with each other; wherein the optical module assembly is at least partially located between the first metal shell and the second metal shell; and wherein the tongue plate is located between the first extension portion and the second extension portion.

Compared with the prior art, the optical module assembly and optical fiber connector of the present disclosure are provided with the substrate. The emitting chip and the silicon photonic chip are both mounted on the substrate. Through the padding effect of the substrate, the optical fiber and the printed circuit board are spaced at a certain distance so as not to interfere with each other.

### BRIEF DESCRIPTION OF DRAWINGS

FIG. 1 is a schematic structural view of an optical module assembly in the related art;

FIG. 2 is a schematic structural view of the optical module assembly in the related art from another angle;

FIG. 3 is a schematic structural view of an optical module assembly in accordance with an embodiment of the present disclosure;

FIG. 4 is a schematic structural view of FIG. 3 from another angle;

FIG. 5 is a working principle diagram of a multi-wavelength emitting silicon photonic chip of the present disclosure;

FIG. 6 is a schematic view of a connection of a multi-wavelength single-channel optical fiber according to the present disclosure;

FIG. 7 is a perspective schematic view of an optical fiber connector in accordance with an embodiment of the present disclosure;

FIG. 8 is a perspective view of FIG. 7 from another angle;

FIG. 9 is a top view of FIG. 7;

FIG. 10 is a top view of FIG. 8;

FIG. 11 is a side view of FIG. 8;

FIG. 12 is a front view of FIG. 7;

FIG. 13 is a rear view of FIG. 8;

FIG. 14 is a partially exploded perspective view of the optical fiber connector in accordance with the embodiment of the present disclosure;

FIG. 15 is a partially exploded perspective view of FIG. 14 from another angle; and

FIG. 16 is a partially exploded perspective view of the optical module assembly in FIG. 14, in which a daughter board and an electrical chip are separated.

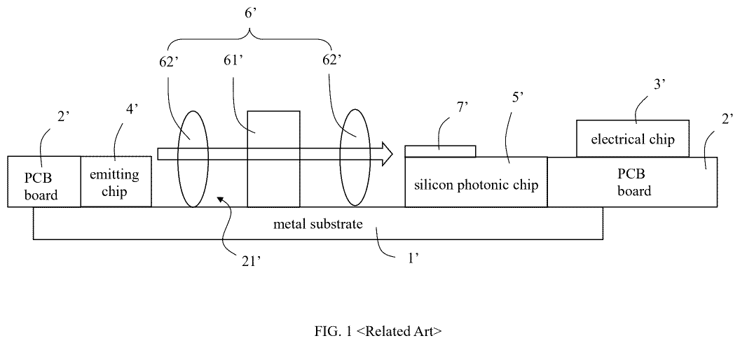

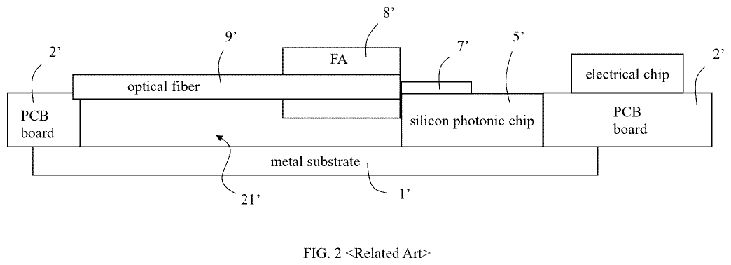

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

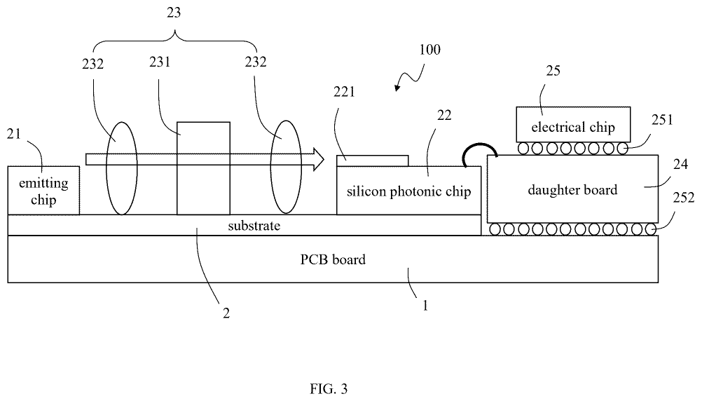

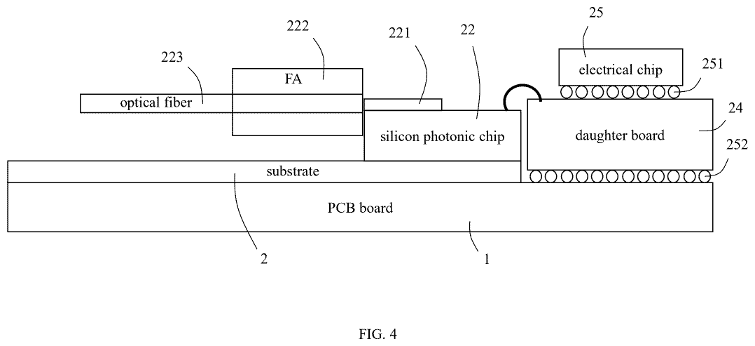

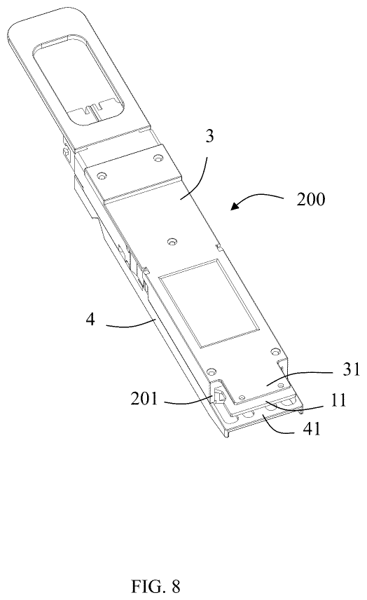

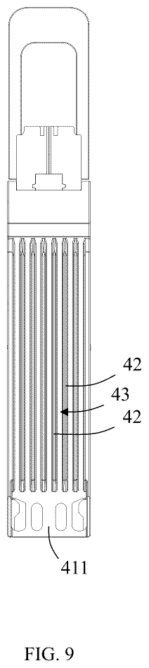

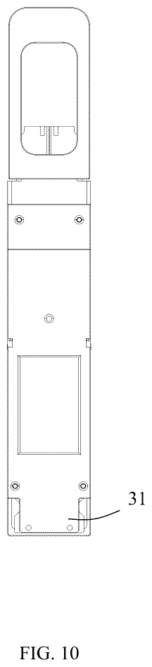

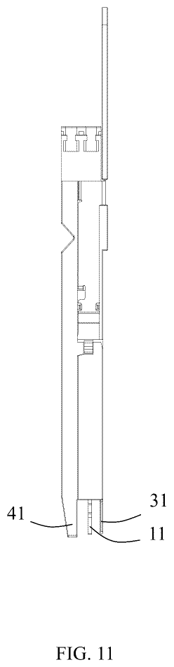

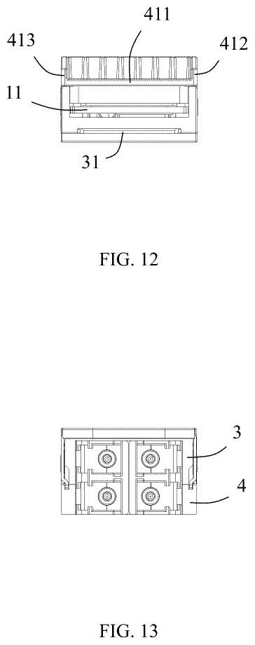

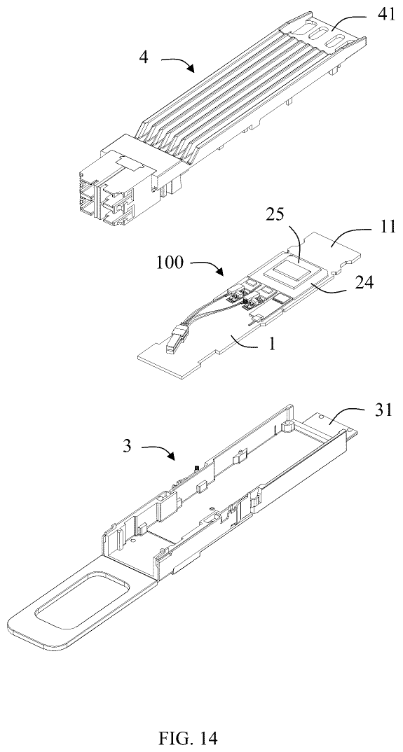

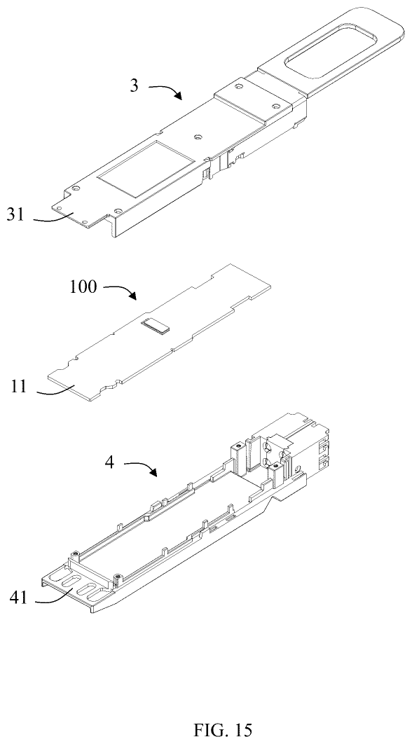

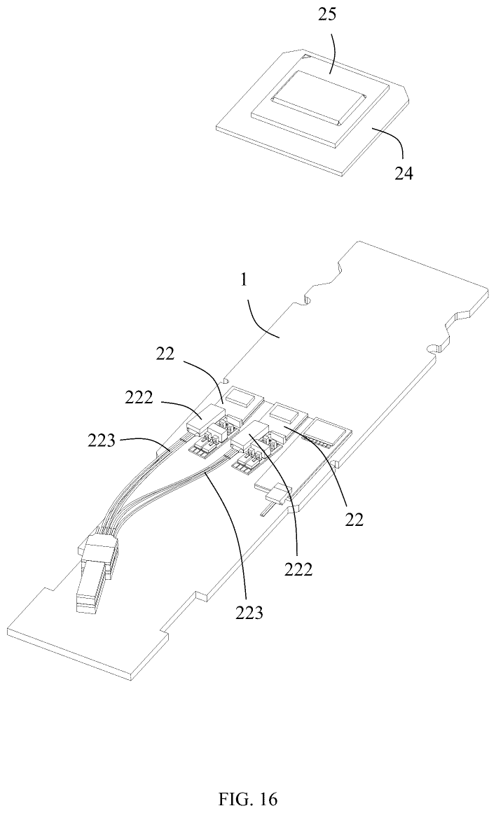

Referring to FIG. 3 to FIG. 16, the present disclosure discloses an optical module assembly 100, which includes a printed circuit board (PCB board) 1, a substrate 2 mounted on the printed circuit board 1, an emitting chip 21 mounted on the substrate 2, a silicon photonic chip 22 mounted on the substrate 2, and an optical module 23 located between the emitting chip 21 and the silicon photonic chip 22. The optical module 23 includes an optical isolator 231 and two lenses 232 which are located on two sides of the optical isolator 231, respectively.

Preferably, the emitting chip 21 and the silicon photonic chip 22 are located at a same height to reduce signal loss as much as possible.

It is understandable to those skilled in the art that the printed circuit board 1 will inevitably undergo a certain degree of deformation during the manufacturing process, resulting in insufficient flatness of its surface. In order to solve this above problem, the present disclosure provides the substrate 2. The flatness of the substrate 2 is high enough to facilitate the mounting of the emitting chip 21 and the silicon photonic chip 22, thereby avoiding possible mounting problems caused by directly mounting the emitting chip 21 and the silicon photonic chip 22 on the printed circuit board 1.

The emitting chip 21 is used to emit optical signals, and the optical signals pass through the optical module 23.

The silicon photonic chip 22 is connected to a waveguide 221. The optical signals passing through the optical module 23 are input into the silicon optical chip 22 through the waveguide 221.

In the illustrated embodiment of the present disclosure, the optical module assembly 100 further includes a daughter board 24 mounted on the printed circuit board 1 and an electrical chip 25 mounted on the daughter board 24. The daughter board 24 may be made of a printed circuit board.

The silicon optical chip 22 is connected to an optical fiber 223 through an optical fiber array (FA) 222. It is understandable to those skilled in the art that in the illustrated embodiment of the present disclosure, the printed circuit board 1 is not provided with any hollow portion for accommodating the emitting chip 21 and the silicon photonic chip 22. Therefore, the structural strength of the printed circuit board 1 is good and the printed circuit board 1 has a relatively large usable area, which is conducive to arranging more electronic components.

In addition, in the illustrated embodiment of the present disclosure, the optical fiber 223 is higher than the printed circuit board 1 so that it will not interfere with the printed circuit board 1.

In one embodiment of the present disclosure, the electrical chip 25 is electrically connected to the daughter board 24 through a plurality of first joint elements 251 (for example, first solder balls). It is understandable to those skilled in the art that after the first solder balls melt, the electrical chip 25 can be fixed together with the daughter board 24.

In addition, in an embodiment of the present disclosure, the daughter board 24 is fixed to the printed circuit board 1 through flip chip bond. For example, the daughter board 24 is electrically connected to the printed circuit board 1 through a plurality of second joint elements 252 (for example, second solder balls). It is understandable to those skilled in the art that after the second solder balls melt, the daughter board 24 can be fixed together with the printed circuit board 1.

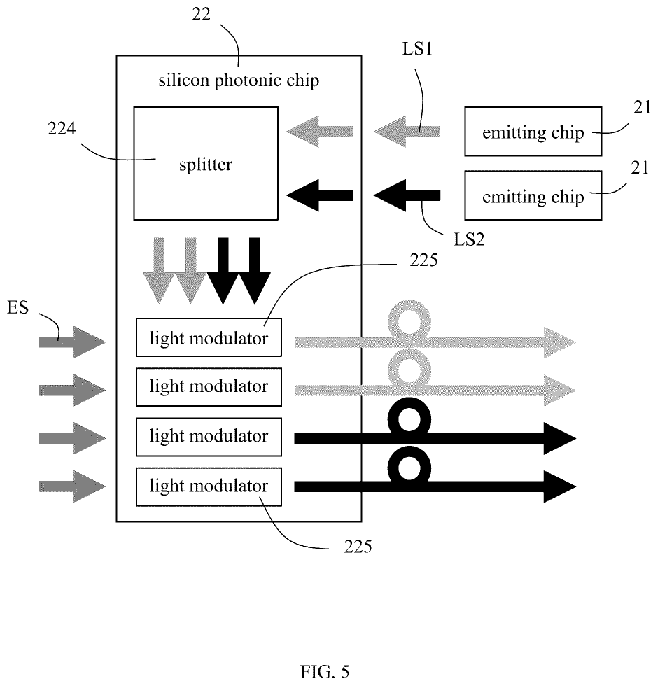

As shown in FIG. 5, in an application of the optical module assembly 100 of the present disclosure, the silicon optical chip 22 of the optical module assembly 100 can be suitable for multi-wavelength dual-channel transmission. At this time, the first optical signal LS1 and the second optical signal LS2 are emitted from the emitting chip 21. The first optical signal LS1 and the second optical signal LS2 have different wavelengths. The silicon photonic chip 22 includes a splitter 224 and a plurality of light modulators 225. The splitter 224 divides the first optical signal LS1 and the second optical signal LS2 into corresponding paths. Then, the optical signals and the electrical signal ES are jointly input into the optical modulator 225 and converted into output signals.

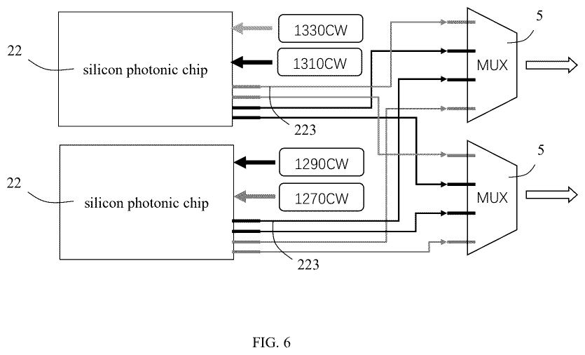

As shown in FIG. 6, the optical module assembly 100 of the present disclosure may have a plurality of silicon photonic chips 22 (for example, two), and use a combination of different wavelength-emitting silicon optical chips 22 and optical fibers 223 to achieve multi-wavelength single channel transmission. For example, optical signals of different continuous waves (for example, 1270CW, 1290CW, 1310CW and 1330CW, respectively) are input to the plurality of silicon photonic chips 22, processed by the silicon photonic chips 22, and then output after operation by multiplexers 5 (MUX).

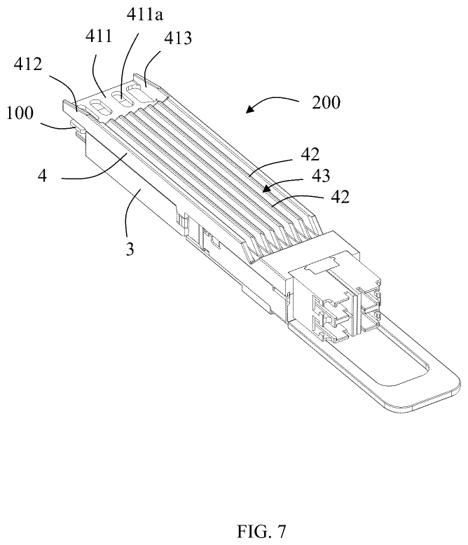

As shown in FIG. 7 to FIG. 16, the present disclosure also discloses an optical fiber connector 200 including the optical module assembly 100. The optical fiber connector 200 includes a first metal shell 3, a second metal shell 4, and the optical module assembly 100 which is at least partially located between the first metal shell 3 and the second metal shell 4.

The optical fiber connector 200 is provided with a mating surface 201. The first metal shell 3 includes a first extension portion 31 protruding beyond the mating surface 201. The second metal shell 4 includes a second extension portion 41 protruding beyond the mating surface 201. In the illustrated embodiment of the present disclosure, the second extension portion 41 is substantially U-shaped, and includes a plate portion 411, a first side wall 412 vertically extending from one side of the plate portion 411 away from the first extension portion 31 and a second side wall 413 vertically extending from another side of the plate portion 411 away from the first extension portion 31. The plate portion 411 defines a plurality of through holes 411a. The second metal shell 4 is provided with a plurality of spaced apart fins 42 and a plurality of grooves 43 of which each is located between two adjacent fins 42. The fins 42 are configured to dissipate heat. The grooves 43 are configured to allow airflow to flow through so as to improve heat dissipation.

The printed circuit board 1 of the optical module assembly 100 includes a tongue plate 11 protruding beyond the mating surface 201. The tongue plate 11 is located between the first extension portion 31 and the second extension portion 41.

Compared with the prior art, the optical module assembly 100 and the optical fiber connector 200 of the present disclosure are provided with the substrate 2. The emitting chip 21 and the silicon photonic chip 22 are both mounted on the substrate 2. Through the padding effect of the substrate 2, the optical fiber 223 and the printed circuit board 1 are spaced at a certain distance so as not to interfere with each other.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. An optical module assembly, comprising:
a printed circuit board;
a substrate, the substrate being mounted on the printed circuit board;
an emitting chip, the emitting chip being mounted on the substrate;
a silicon photonic chip, the silicon photonic chip being mounted on the substrate;
an optical fiber, the optical fiber being connected to the silicon optical chip to transmit optical signals;
a daughter board, the daughter board being mounted on the printed circuit board; and
an electrical chip, the electrical chip being mounted on the daughter board;
wherein the optical fiber and the printed circuit board are separated by a distance so as not to interfere with each other.

2. The optical module assembly according to claim 1, wherein the emitting chip and the silicon photonic chip are located at a same height.

3. The optical module assembly according to claim 1, further comprising an optical module located between the emitting chip and the silicon photonic chip.

4. The optical module assembly according to claim 3, wherein the optical module comprises an optical isolator and two lenses which are located on two sides of the optical isolator, respectively.

5. The optical module assembly according to claim 3, wherein the silicon photonic chip is connected to a waveguide; and the optical signals passing through the optical module are input into the silicon optical chip through the waveguide.

6. The optical module assembly according to claim 1, wherein the electrical chip is electrically and mechanically connected to the daughter board through a plurality of first joint elements.

7. The optical module assembly according to claim 1, wherein the daughter board is fixed to the printed circuit board through flip chip bond.

8. The optical module assembly according to claim 7, wherein the daughter board is electrically and mechanically connected to the printed circuit board through a plurality of second joint elements.

9. The optical module assembly according to claim 1, wherein at least two silicon optical chips are provided, and the at least two silicon optical chips are suitable for multi-wavelength dual-channel transmission.

10. An optical fiber connector, comprising:
a first metal shell, the first metal shell comprising a first extension portion;
a second metal shell, the second metal shell comprising a second extension portion; and
an optical module assembly, the optical module assembly, comprising:
a printed circuit board, the printed circuit board comprising a tongue plate;
a substrate, the substrate being mounted on the printed circuit board;
an emitting chip, the emitting chip being mounted on the substrate;
a silicon photonic chip, the silicon photonic chip being mounted on the substrate;
an optical fiber, the optical fiber being connected to the silicon optical chip to transmit optical signals;
a daughter board, the daughter board being mounted on the printed circuit board; and
an electrical chip, the electrical chip being mounted on the daughter board;
wherein the optical fiber and the printed circuit board are separated by a distance so as not to interfere with each other;
wherein the optical module assembly is at least partially located between the first metal shell and the second metal shell; and
wherein the tongue plate is located between the first extension portion and the second extension portion.

11. The optical fiber connector according to claim 10, wherein the emitting chip and the silicon photonic chip are located at a same height.

12. The optical fiber connector according to claim 10, wherein the optical module assembly further comprises an optical module located between the emitting chip and the silicon photonic chip.

13. The optical fiber connector according to claim 12, wherein the optical module comprises an optical isolator and two lenses which are located on two sides of the optical isolator, respectively.

14. The optical fiber connector according to claim 12, wherein the silicon photonic chip is connected to a waveguide; and the optical signals passing through the optical module are input into the silicon optical chip through the waveguide.

15. The optical fiber connector according to claim 10, wherein the electrical chip is electrically and mechanically connected to the daughter board through a plurality of first joint elements.

16. The optical fiber connector according to claim 10, wherein the daughter board is fixed to the printed circuit board through flip chip bond.

17. The optical fiber connector according to claim 16, wherein the daughter board is electrically and mechanically connected to the printed circuit board through a plurality of second joint elements.

18. The optical fiber connector according to claim 10, wherein at least two silicon optical chips are provided, and the at least two silicon optical chips are suitable for multi-wavelength dual-channel transmission.
